(19) United States
(12) Patent Application Publication
(10) Pub. No.: US 2009/0051026 A1
(43) Pub. Date: Feb. 26, 2009

(54) PROCESS FOR FORMING METAL FILM AND RELEASE LAYER ON POLYMER

(75) Inventors: S. Jay Chey, Ossining, NY (US); Yves C. Martin, Ossining, NY (US); Theodore G. van Kessel, Millbrook, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/841,120

(22) Filed: Aug. 20, 2007

(51) Int. Cl. H01L 21/50; H01L 23/34

(52) U.S. Cl. 257/712; 438/653; 257/E23.087; 257/E21.499

(57) ABSTRACT

A process for forming a releasable metal film includes depositing a metal onto a polymeric sheet such that the metal layer provides a low adhesive interface and exhibits relatively low stress. A barrier layer is then deposited onto the surface of the low adhesion interface. A thin film of a stress relief layer of silicon dioxide, aluminum oxide, copper or aluminum is then deposited followed by addition of a second barrier layer onto the stress relief layer. The stress relief layer provides compressive relief to balance the tensile stress of the so-stacked metal films. An additional solderable layer maybe added for soldering applications. To fabricate the working device with sputtering tools, an extremely high gas pressure is used to achieve low adhesion force between the wettable metallic layer and the polymeric carrier film.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention generally relates to a process for forming a metal film and release layer on a polymer substrate, wherein the metal layer is releasably bonded to the polymer substrate. The released metal film is suitable for use as a conductive thermal interface, IO interconnect, solder applications, and the like.

2. Description of Background

Electronic devices tend to generate large amounts of heat during operation, which must be dissipated by some means to avoid failure or malfunction of the device. Heat dissipation beyond that which is attainable by air circulation can be achieved by attaching a heat sink or other thermal dissipation device to the electronic component. Thermal or electrical interfaces are commonly used to attach such thermal dissipation devices to a heat-emitting component. Interfaces used in the semiconductor industry typically comprise metal interfaces or polymer adhesives filled with conductive fillers.

Metal interfaces, or metallic thermal interface materials, are the preferred interfaces for high power applications. Metallic thermal interface materials are used to conduct heat from a computer chip to a chip lid or heat sink. The computer chip is typically comprised of silicon. The heat sink or chip lid is typically comprised of copper or aluminum and may additionally be plated with nickel or chrome as a protective layer. Metallic thermal interfaces are primarily comprised of metals such as indium, gallium, bismuth, silver, lead, and tin but may include other metals. The interfaces are typically characterized as low melting point alloys or solders and are usually softer than the surfaces being joined. Metallic thermal interface materials may be in a liquid or solid state during use and are also characterized by high thermal conductivity relative to the thermal greases, gels, and polymers in common use.

The ability to create a metallic join to a given surface depends on the ability of the solder to wet the surface and on the formation of intermetallic alloys at the junction. In usual practice, surface oxides are removed with chemical flux in the presence of heat. This is relatively easy when soldering to metals such as copper or nickel but may not be effective with other metals such as aluminum or with non-metallic species such as silicon. Alternatively, it may be desirable, even in the case of solderable metals, to avoid the use of chemicals such as chlorides that may be present in flux and may cause subsequent corrosion. Finally, some metals in common use are incompatible with certain solder materials. An example is aluminum and gallium. Gallium will rapidly corrode aluminum. In such cases, a barrier layer is often used to isolate the metal interface material from the substrate.

It is useful in the above cases to coat the surface to be joined with a wetting layer material and/or solderable layer material and/or barrier layer material that is both free of oxide and able to join with the solder without adverse intermetallic formation. It is also desirable to be able to place such a wetting layer material and/or solderable layer material and/or barrier layer on an otherwise difficult to join surfaces such as silicon. This coating can be accomplished directly by the use of vacuum deposition including evaporation and/or sputtering. These methods are often inconvenient and too costly to implement.

Alternatively, the coating can be deposited on a carrier film and then bonded to a substrate using adhesives. The carrier film is then peeled leaving behind the desired coating. This method is referred to as the foil transfer process. This method has been found to be a convenient, effective and low cost method of placing a solder bonding layer on most substrates. In the foil transfer process, the layers of the foil are deposited in reverse order on the carrier film. When complete, the top surface of the foil is bonded to the substrate using suitable adhesives. The backing foil is then removed leaving behind the metal foil with the desired properties.

Forming a stable metallic layer on the carrier film that easily peels off requires controlling the deposition parameters precisely. Too much stress in the coating can cause premature film release, and too good of an adhesion can prevent the coating from peeling off altogether. The present invention addresses these issues and provides a structure (carrier film and coating) and process that overcomes the problems noted in the prior art.

### SUMMARY OF THE INVENTION

The shortcomings of the prior art are overcome and additional advantages are provided through the provision of a process for forming a metal release layer on a carrier film. The released metal layer is suitable for use as a thermal interface material, an IO interconnect, and solder applications and the like.

In one embodiment, a process for forming a releasable metallic film on a carrier polymer substrate comprises evaporating a wettable metal layer such as by thermal evaporation, electron beam evaporation, and the like, onto a polymeric substrate, wherein the wettable metal layer comprises gold, platinum, or palladium. A barrier metal layer of a refractory metal is then deposited onto the wettable metal layer.

In one embodiment, the barrier metal layer can be comprised of an alternating stack of a barrier metal layer and a stress relief layer. The stress relief layer has compressive stress to offset the tensile stress of the barrier metal layer. This allows a thicker barrier layer to be deposited without having the thin film stress to cause premature delamination. Suitable stress relief layers include wherein the stress relief layer are selected from a group consisting of silicon dioxide, aluminum oxide, copper, and aluminum.

In another embodiment, the metal stack on a polymeric carrier film can be used for solder applications. In this embodiment, three layers define the metal stack. The first metal layer, e.g., gold, is a wettable layer, or the oxide protection layer. The second layer is the solderable layer, e.g., nickel or copper, or nickel or copper with small amount of other metals such as vanadium or silicon. The third layer is a barrier layer, e.g., titanium, chromium and the like.

In another embodiment, the process for forming a releasable metallic film on a carrier polymer substrate process comprises magnetron sputter depositing a wettable metal layer onto a polymeric substrate, wherein the wettable layer comprises gold, platinum, palladium, and combinations thereof at a pressure of 20 mTorr to 200 mTorr; depositing a barrier layer (Ti, Cr or other refractory metals) of 1,000 to 5,000 A. Generally speaking, sputtering deposition of wettable layer on the polymeric substrate is not a good idea as the adhesion is too strong for the foil transfer process. However, operating at higher than normal pressures e.g., at pressures of 20 mTorr to 200 mTorr, has been found to reduce the adhesive force and allows commercial sputtering tools to fabricate the devices at a low cost.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter, which is regarded as the invention, is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a releasable metal structure disposed on a polymeric sheet in accordance with one embodiment;

FIG. 2 illustrates a process for forming a releasable metal layer; and

FIG. 3 illustrates a releasable metal structure disposed on a polymeric sheet in accordance with another embodiment

### DETAILED DESCRIPTION OF THE INVENTION

The detailed description explains the preferred embodiments of the invention, together with advantages and features, by way of example with reference to the drawings.

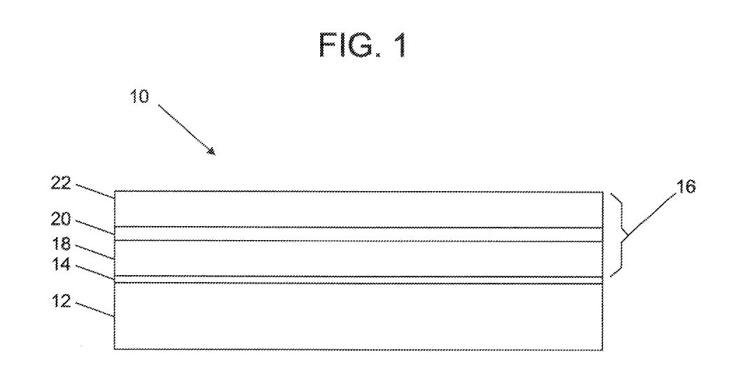

Disclosed herein are a metal release structure and processes for forming the metal release structure. FIG. 1 schematically illustrates the metal release structure 10 disposed on a carrier substrate 12. The carrier substrate can be a high temperature polymeric material, such as a polyimide, that is stable to the particular fabrication processes for forming the metal release structure 10. The metal release structure includes a low adhesion interface 14 of a sputtered or evaporated metal such as gold, platinum, palladium or the like. Modifying the deposition conditions as will be described in greater detail below, provides the weak adhesive interface.

A stress-balanced stack, shown generally at 16, is disposed on the surface of the low adhesion interface 14. The stress-balanced stack 16 includes a silicon dioxide stress relief layer 20 intermediate refractory metal layers, 18, 22. The metal release film or structure can be used as a thermal interface such as those thermal interfaces disclosed in U.S. patent application Ser. No. 11/220,878, incorporated herein by reference in its entirety, which may be disposed between a die and another heat transfer element, such as a heat spreader or heat sink.

By utilizing the stress relief layer 20, minimal stress can be obtained in the total stack that includes the refractory metal layers 18, 22. The total thickness of refractory metal layers remains the same as if only one layer were employed, however, the SiO₂ with compressive stress intersects the refractory metal layers to provide stress relief that would normally occur as a function of increased thickness. For example, titanium is initially low in compressive stress but becomes tensile at thicknesses greater than about 1000 angstroms and continues to increases in tensile stress with increasing thickness. For use as barrier layers, it is desirable to have a thickness of about 2000 angstroms or greater. The use of a stress relief layer 20 permits the thickness of the titanium layer to be obtained without the stress loadings of a single layer at the same thickness.

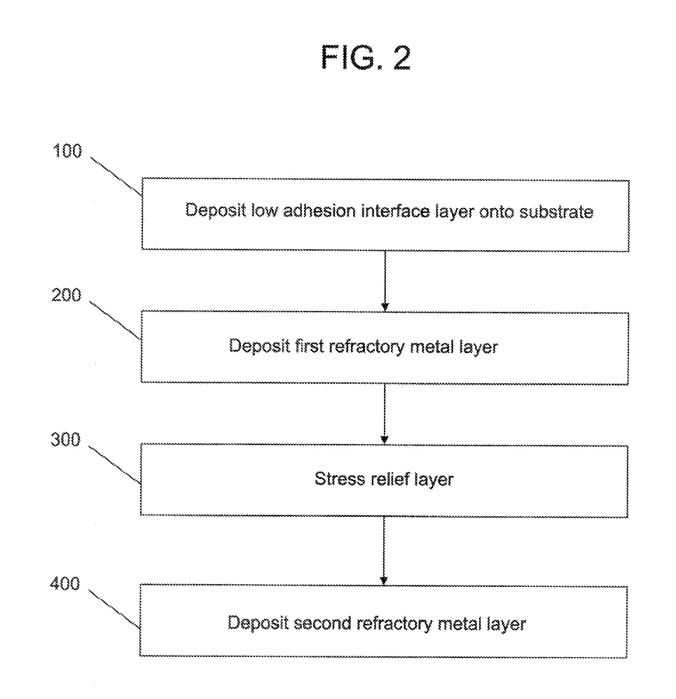

As shown in the FIG. 2, the process generally includes step 100, which includes sputter depositing a gold layer onto a substrate under sputtering conditions that form a weak interface between the gold layer and the substrate surface and provide the film with low stress. Suitable sputtering processes include, without limitation, sputtering; diode sputtering; magnetron sputtering; DC sputtering; bias sputtering; RF sputtering; and the like.

In one embodiment, the sputtering process utilizes relatively high pressures to frangibly fuse the gold layer to the underlying polymeric substrate, i.e., carrier. By way of example, a typical magnetron sputtered gold coating operates at 1 mTorr to 10 mTorr pressures and results in excellent adhesion to the underlying support. In the present disclosure, the magnetron sputtering pressures are from 20 mTorr to 200 mTorr in one embodiment. The relatively high pressures provide a weak interface between the gold layer and the substrate surface and provide the film with low stress. The thickness of the gold layer is from 100 to 2000 angstroms (Å) in one embodiment. The resulting film has a relatively weak adhesive force between the gold and the substrate. This allows the overlying film to be easily detached but not too easily as would be the case of high stress film. The pulling force to detach the film is typically in a range of 0.05 to 0.2 lb/in (pound per inch).

Optionally, the gold layer may be deposited by an evaporation process, which generally provides a lower adhesive strength than a conventional sputtering process operated at the typical pressures of 1 to 10 mTorr. Suitable evaporation processes include, without limitation, PVD, CVD, APCVD, PECVD, sputter, LPCVD, ion plating, flame hydrolysis, and the like.

The substrate can be a polymeric substrate. Suitable polymeric substrates include high temperature polymers that can withstand the sputtering environment such as, without limitation, polyimides, teflon etc. Suitable polyimides are those commercially available under the tradenames UPILEX and KAPTON. Other suitable substrates include polytetrafluoroethylene commercially available under the tradename TEFLON. The thickness of the substrate can vary but is generally preferred to be about 50 to 150 micrometer.

As shown in step 200, a refractory metal layer is then deposited onto the gold layer and can be used form a barrier layer as may be desired for some applications. Refractory metals are generally known for their resistance to heat, wear, and corrosion. Suitable refractory metals include rhenium, osmium, tantalum, molybdenum, iridium, niobium, ruthenium, hafnium, zirconium, vanadium, chromium, and titanium. Of these, titanium and chromium are preferred. The refractory metal layer can be sputter deposited and for use as a barrier layer is at a thickness effective to prevent diffusion. The thickness of the refractor metal layer can be about 500 to 5000 Å.

In step 300, the stress relief layer is deposited onto the refractory metal layer. Suitable materials to form the stress relief layer include silicon dioxide, aluminum oxide, copper, and aluminum. The stress relief layer is at a thickness effective to provide compressive stress so as to balance the tensile stress of the refractory metal layers. In one embodiment, the thickness of the silicon dioxide is 100 to 500 Å. The silicon dioxide layer can be sputter deposited in a conventional manner.

In step 400, an additional refractory metal layer is deposited onto the silicon dioxide layer. The thickness of the additional refractory layer can be about 500 to 2000 Å. Thus, the same overall thicknesses of refractory metal in layers 18, 22 (see FIG. 1) can be used albeit at individually lower stress values. In a preferred embodiment, the refractory layers as defined in steps 200 and 400 are deposited at about the same thickness.

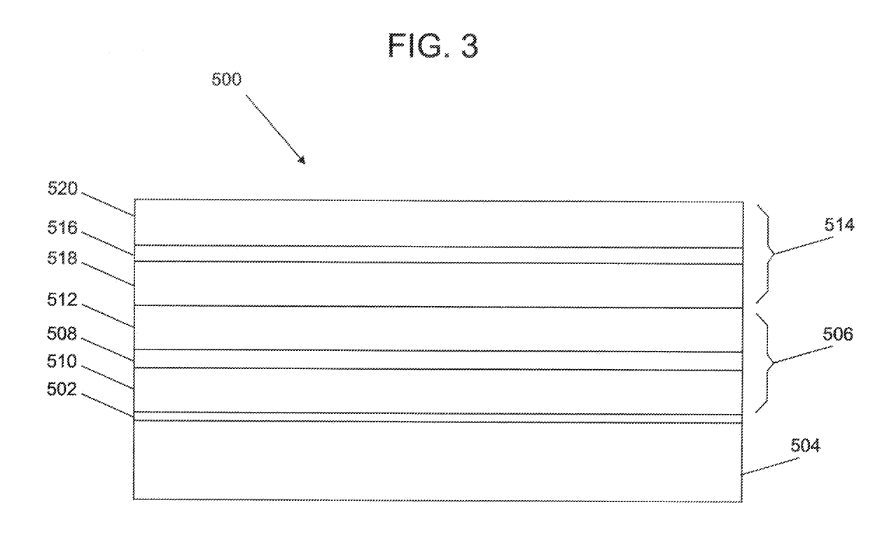

In an alternative embodiment, the use of the releasable metal film structure can be modified so as to permit utilization in soldering applications. As shown in FIG. 3, the metal release structure 500 includes multiple stacks disposed on a low adhesion interface 502. The low adhesion interface is formed on a polymeric substrate 504 in the manner previously described such that the film provides a low adhesive force and exhibits low stress. The low adhesion interface can be formed of one or more layers.

The first stack disposed on the low adhesion interface 502 is a solderable stack 506. The solderable stack 506 includes a stress relief and/or a diffusion barrier material 508 intermediate layers of solderable materials 510, 512. Suitable stress relief and/or a diffusion barrier material include, without limitation, silicon dioxide, Aluminum oxide, copper, aluminum and the like. The solderable materials include, without limitation, nickel, nickel vanadium, gold, nickel silicon, copper, copper vanadium, and copper silicon, and various combinations thereof.

Disposed on the solderable stack is a barrier stack 514, which includes stress relief and/or a diffusion barrier material 516 such as silicon dioxide, aluminum oxide, copper, aluminum and the like, sandwiched between refractory metal layers 518, 520 such as titanium, chromium, vanadium, molybdenum, nickel, iron and the like.

The thicknesses of the various layers described above are similar to those described in relation to FIG. 2. That is, thickness of layers 510, 512, 518, 520 can be about 500 to 2000 Å. The thickness of the stress relief layers 508, 516 can be 100 to 500 Å. The thickness of the low adhesion interface layer 502 is from 100 to 1000 angstroms (Å)

The invention is further illustrated by the following non-limiting example.

### EXAMPLE 1

In this example, a metal structure was releasably formed on a polymer sheet. Gold was sputter deposited at 50 mTorr onto a polyimide polymeric sheet commercially available under the tradename Upilex. The polyimide polymeric sheet had a thickness of 100 micrometer. The thickness of the gold layer was about 500 A. Then, titanium was sputter deposited onto the gold layer at a thickness of about 1000 Å.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A process for forming a releasable metallic film on a polymeric substrate, the process comprising:
depositing a wettable metal layer onto a polymeric substrate, wherein the wettable layer comprises gold, platinum, palladium, and combinations thereof; and
depositing a barrier layer comprising of first refractory metal layer selected from a group consisting of titanium, chromium, tungsten, vanadium, and tantalum to form the releasable metal film.

2. The process of claim 1, wherein the wettable metal layer has a thickness of 100 to 1000 angstroms and the barrier layer has a thickness of 500 to 5000 angstroms.

3. The process of claim 1, wherein depositing the barrier layer comprises depositing the first refractory metal layer onto the wettable metal layer, a stress relief layer onto the first refractory metal layer and a second refractory metal layer onto the stress relief layer, wherein the stress relief layer is selected from a group consisting of silicon dioxide, aluminum oxide, copper, and aluminum.

4. The process of claim 1, further comprising depositing a solderable layer intermediate the wettable metal layer and baffler layer, wherein the solderable layer is a metal selected from the group consisting of copper, gold, nickel, silicon, vanadium, and combinations thereof.

5. A device comprising the releasable metal film of claim 1 intermediate a die and a heat transfer element.

6. A process for forming a releasable metallic film on a polymeric substrate, the process comprising:
sputter depositing a wettable metal layer onto the polymeric substrate, wherein the wettable layer comprises gold, platinum, palladium, and combinations thereof at a pressure of 20 mTorr to 100 mTorr; and
depositing a barrier layer comprising a first refractory metal layer selected from a group consisting of titanium, chromium, tungsten, vanadium, and tantalum.

7. The process of claim 6, wherein the wettable metal layer has a thickness of 100 to 1000 angstroms and the barrier layer have a thickness of 500 to 5000 angstroms.

8. The process of claim 6, wherein depositing the barrier layer comprises depositing the first refractory metal layer onto the wettable metal layer, a stress relief layer onto the first refractory metal layer and a second refractory metal layer onto the stress relief layer, wherein the stress relief layer is selected from a group consisting of silicon dioxide, aluminum oxide, copper, and aluminum.

9. A device comprising the releasable metal film of claim 6 intermediate a die and a heat transfer element or intermediate a die and other electrical or optical component.

10. The process of claim 6, further comprising depositing a solderable layer intermediate the wettable metal layer and baffler layer, wherein the solderable layer is a metal selected from the group consisting of copper nickel, silicon, vanadium, and combinations thereof.

11. The process of claim 10, where the solderable layer contains a stress-relief layer selected from a group consisting of silicon dioxide, aluminum oxide, copper, and aluminum.
